(19) United States
(12) Patent Application Publication
(10) Pub. No.: US 2019/0369429 A1
(43) Pub. Date: Dec. 5, 2019

(54) ARRAY SUBSTRATE MANUFACTURING METHOD, ARRAY SUBSTRATE, DISPLAY PANEL AND DISPLAY DEVICE

(71) Applicant: Wuhan China Star Optoelectronics Technology Co., Ltd., Wuhan (CN)

(72) Inventor: Zhihao Cao, Shenzhen (CN)

(21) Appl. No.: 16/211,517

(22) Filed: Dec. 6, 2018

Related U.S. Application Data
(63) Continuation of application No. PCT/CN2018/096512, filed on Jul. 20, 2018.

(30) Foreign Application Priority Data
May 29, 2018 (CN) 201810534402.8

(51) Int. Cl. G02F 1/1333; H01L 27/12; G02F 1/1343; G06F 3/041

(52) U.S. Cl. CPC G02F 1/13338; H01L 27/1248; H01L 27/1288; G02F 1/1368; G06F 3/0412; G02F 2201/121; G02F 1/13439

(57) ABSTRACT

An array substrate manufacturing method, an array substrate, a display panel and a display device are disclosed. The array substrate comprises a planarization layer and common touch electrodes located on the planarization layer, wherein the planarization layer is provided with a plurality of convex areas and a plurality of concave areas, and the common touch electrodes are disposed in the concave areas. In this way, abnormal display of the display panel caused by gap inconsistencies may be effectively avoided.

### CROSS REFERENCE TO RELATED APPLICATIONS

The present application is a continuation-application of International (PCT) Patent Application No. PCT/CN2018/096512, filed on Jul. 20, 2018, which claims foreign priority of Chinese Patent Application No. 201810534402.8, filed on May 29, 2018 in the National Intellectual Property Administration of China, the entire contents of which are hereby incorporated by reference.

### TECHNICAL FIELD

The present disclosure relates to the technical field of displays, in particular to an array substrate manufacturing method, an array substrate, a display panel and a display device.

### BACKGROUND

In the field of touch displays, common touch electrodes are generally partitioned in a checkerboard shape to sense finger touch signals on the corresponding checkerboard cells that are covered with a dielectric layer for insulation. As the common touch electrodes are partitioned, if the cross section is uneven, after cell fabrication, products are prone to deformation under the influence of self gravity, and a gap inconsistency is likely to be caused, resulting in abnormal display.

### SUMMARY

The main issue to be settled by the present disclosure is to provide an array substrate manufacturing method, an array substrate, a display panel and a display device, which may effectively avoid abnormal displays caused by gap inconsistencies of display panels.

To settle the aforesaid technical issue, one technical solution adopted by the present disclosure is to provide an array substrate. The array substrate comprises a planarization layer and common touch electrodes located on the planarization layer, wherein the planarization layer is provided with a plurality of concave areas which are distributed in an array manner, and the common touch electrodes are disposed in the concave areas.

To settle the aforesaid technical issue, another technical solution adopted by the present disclosure is to provide an array substrate manufacturing method. The array substrate manufacturing method comprises providing a substrate; and sequentially manufacturing a planarization layer and common touch electrodes on the substrate to form an array substrate, wherein the planarization layer is provided with a plurality of convex areas and a plurality of concave areas, and the common touch electrodes are disposed in the concave areas.

To settle the aforesaid technical issue, another technical solution adopted by the present disclosure is to provide a display panel. The display panel comprises an array substrate, a color filter substrate and a liquid crystal layer located between the color filter substrate and the array substrate, wherein the array substrate comprises a planarization layer and common touch electrodes located on the planarization layer, the planarization layer is provided with a plurality of convex areas and a plurality of concave areas, the common touch electrodes are disposed in the concave areas, and the shape of the color filter substrate corresponds to the shape of the array substrate.

By adoption of the above technical solutions, the present disclosure has the following beneficial effects: the array substrate may comprise the planarization layer and the common touch electrodes which are disposed in a stacked manner; the planarization layer may be provided with a plurality of convex areas and a plurality of concave areas, and the common touch electrodes may be disposed in the concave areas; the planarization layer may be provided with the convex areas, so that the distance between the planarization layer and the color filter substrate of the display panel may be decreased in the convex areas, thus, effectively overcoming the defect of the gap inconsistency of the color filter substrate caused by gravity after cell fabrication and effectively avoiding abnormal display of the display panel caused by gap inconsistencies.

### BRIEF DESCRIPTION OF THE DRAWINGS

In order to more clearly explain the technical solutions provided by embodiments of the invention, a brief description of the drawings used for describing these embodiments is given below. Apparently, the drawings in the following description are only for certain illustrative embodiments of the invention, and for those ordinarily skilled in this field, other drawings can be obtained without creative labor based on the following drawings.

FIG. 1 is a structural view of a display panel in the related art.

FIG. 2 is a structural view of one embodiment of an array substrate of the present disclosure.

FIG. 3 is a structural view of another embodiment of the array substrate of the present disclosure.

FIG. 4 is a flow diagram of one embodiment of an array substrate manufacturing method of the present disclosure.

FIG. 5 is a structural view of an array substrate in one embodiment of the array substrate manufacturing method of the present disclosure.

FIG. 6 is a flow diagram of another embodiment of the array substrate manufacturing method of the present disclosure.

FIG. 7 is structural view of a substrate, a planarization layer and a photoresist formed in another embodiment of the array substrate manufacturing method of the present disclosure.

FIG. 8 is a structural view after exposure and etching in another embodiment of the array substrate manufacturing method of the present disclosure.

FIG. 9 is a structural view of an array substrate in another embodiment of the array substrate manufacturing method of the present disclosure.

FIG. 10 is a structural view of one embodiment of a display panel of the present disclosure.

FIG. 11 is a structural view of one embodiment of a display device of the present disclosure.

### DETAILED DESCRIPTION

A clear and complete description of the technical solutions provided by embodiments of the present disclosure is given below with reference to the accompanying drawings. Apparently, the embodiments described below are only certain illustrative ones, but do not include all possible embodiments of the present disclosure. All other embodiments obtained by those ordinarily skilled in this field based on these illustrative embodiments without creative work should also fall within the protection scope of the present disclosure.

Touch display devices may fulfill a display function as well as a touch function. Existing touch display devices generally comprise a touch display panel, which in turn typically comprises a display panel and a touch panel. Embedded-type (In-cell) touch display panels may facilitate production of light and thin products, thereby having been widely studied and applied.

As the embedded-type touch display panels have both the touch function and the display function, which means that both a touch circuit and a display circuit are manufactured on thin film transistor array substrates, the penetrability is improved, and electronic display equipment such as mobile phones may be made lighter and thinner.

FIG. 1 is a structural view of a display panel in the related art. As shown in FIG. 1, the display panel comprises a color filter substrate 11, support columns 12 and an array substrate 13. The array substrate 13 comprises a dielectric layer 131, common touch electrodes 132 and a planarization layer 133. As the common touch electrodes 132 are separated, the part, between every two adjacent common touch electrodes 132, of the dielectric layer 131 is concaved downwards, which results in an uneven cross section, and consequentially, after cell fabrication, the color filter substrate 11 deforms at the concaved parts of the dielectric layer 131 under the influence of self gravity, and abnormal display is caused.

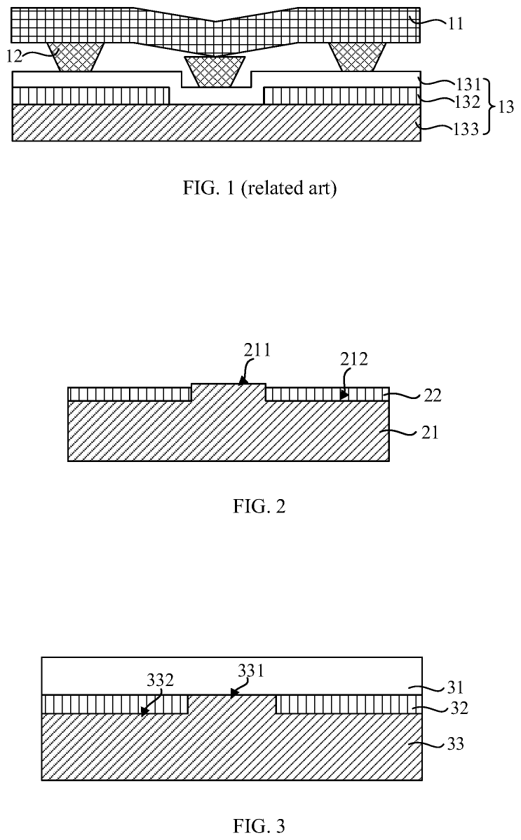

FIG. 2 is a structural view of one embodiment of an array substrate of the present disclosure. The array substrate in the present disclosure may comprise a planarization layer 21 and common touch electrodes 22 located on the planarization layer 21.

The planarization layer 21 may be provided with a plurality of convex areas 211 and a plurality of concave areas 212 which are distributed in an array manner. The common touch electrodes 22 may be disposed in the concave areas 212.

A substrate, a gate layer, an active layer, a source/drain layer and an insulation layer (not shown) may be located below the planarization layer 21.

The convex areas 211 of the planarization layer 21 may be used to overcome the defect of gap inconsistency of the color filter substrate caused by gravity after cell fabrication, so that gap differences of the display panel may be reduced after cell fabrication, the performance and yield of the touch display panel may be ensured, and abnormal display of the display panel caused by gap inconsistencies may be effectively avoided.

Unlike the related art, the planarization layer of the array substrate in this embodiment may be provided with the plurality of convex areas and the plurality of concave areas which are distributed in an array manner, and the common touch electrodes may be disposed in the concave areas; the planarization layer may be provided with the convex areas and the distance between the planarization layer and the color filter substrate of the display panel may be decreased in the convex areas, so that the gap inconsistency of the color filter substrate caused by gravity after cell fabrication may be avoided, and abnormal display of the display panel caused by gap inconsistencies may be effectively prevented.

Please refer to FIG. 3 which is a structural view of another embodiment of the array substrate of the present disclosure. The array substrate may comprise a planarization layer 33 and common touch electrodes 32 located on the planarization layer 33.

The planarization layer 33 may be provided with a plurality of convex areas 331 and a plurality of concave areas 332 which are distributed in an array manner. The common touch electrodes 32 may be disposed in the concave areas 332 and may have a thickness identical with a height of the convex areas 331.

The convex areas 331 may be a part of the planarization layer 33 and are formed through etching; or the convex areas 331 may be not the part of the planarization layer 33 and may be formed by filling other filler materials in the planarization layer 33.

Preferably, the common touch electrodes 32 may be made from indium tin oxide and may have a thickness of 60 nm.

The array substrate further may comprise a dielectric layer 31. The planarization layer 33 and the common touch electrodes 32 may be covered with the dielectric layer 31.

As the thickness of the common touch electrodes 32 may be identical with the height of the convex areas 331, the surface of the array substrate may be flat, so that the defect of the gap inconsistency of the color filter substrate caused by gravity after cell fabrication may be overcome, and all gaps of the display panel may be kept consistent after cell fabrication, thus, ensuring the performance and yield of the touch display panel and effectively avoiding abnormal display caused by gap inconsistencies of the display panel.

Different from the related art, the planarization layer of the array substrate in this embodiment may be provided with the plurality of convex areas and the plurality of concave areas which are distributed in an array manner, the common touch electrodes may be disposed in the concave areas, and the thickness of the common touch electrodes may be kept identical with the height of the convex areas, so that the surface of the dielectric layer may be flat, and thus the gap inconsistency of the color filter substrate caused by gravity after cell fabrication is effectively prevented, and abnormal display of the display panel caused by gap inconsistencies may be effectively avoided.

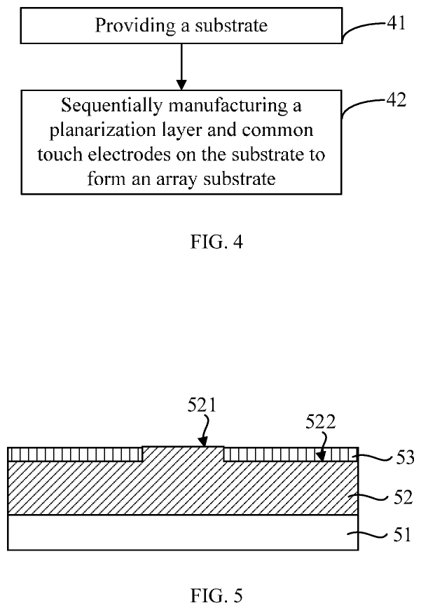

Please refer to FIG. 4 and FIG. 5, FIG. 4 is a flow diagram of one embodiment of an array substrate manufacturing method of the present disclosure. The array substrate manufacturing method may comprise the following blocks:

Block 41, a substrate may be provided.

Block 42, a planarization layer and common touch electrodes may be sequentially manufactured on the substrate to form an array substrate.

Particularly, a planarization layer 52 and common touch electrodes 53 may be sequentially manufactured on a substrate 51 to form an array substrate. The planarization layer 52 may be provided with a plurality of convex areas 521 and a plurality of concave areas 522.

Different from the related art, the array substrate manufacturing method in this embodiment may comprise the blocks of providing the substrate and then sequentially manufacturing the planarization layer and the common touch electrodes on the substrate to form the array substrate; the planarization layer may be of a structure provided with the plurality of convex areas and the plurality of concave areas, and the common touch electrodes may be disposed in the concave areas to avoid surface unevenness of the array substrate, so that the defect of gap inconsistency of a color filter substrate caused by gravity after cell fabrication may be effectively overcome, and abnormal display of a display panel caused by gap inconsistencies may be prevented.

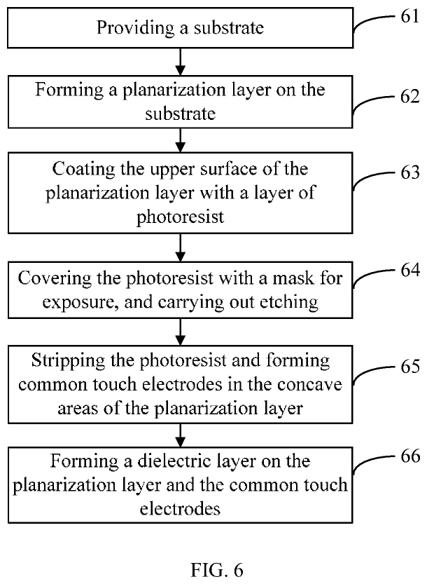

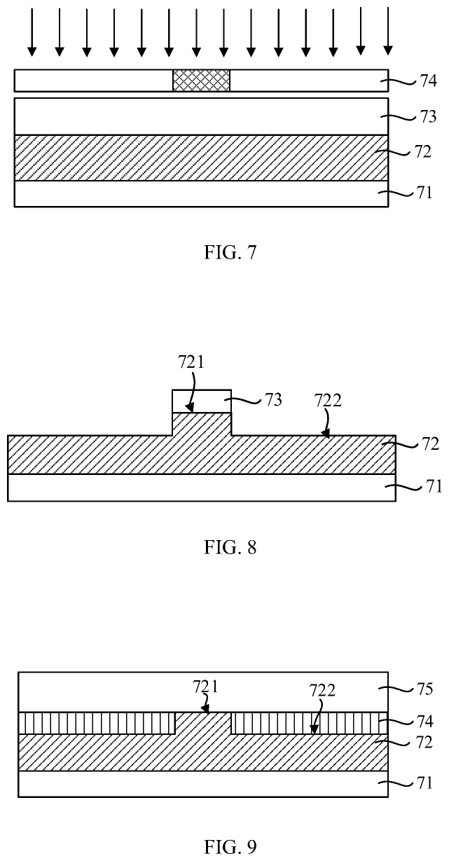

Please refer to FIGS. 6-9, FIG. 6 is a flow diagram of another embodiment of the array substrate manufacturing method of the present disclosure. The array substrate manufacturing method may comprise the following blocks:

Block 61, a substrate may be provided.

Block 62, a planarization layer may be formed on the substrate.

Block 63, an upper surface of the planarization layer may be coated with a layer of photoresist.

Particularly, a planarization layer 72 may be formed on a substrate 71, and the upper surface of the planarization layer 72 may be coated with a layer of photoresist 73. The photoresist 73 may be positive photoresist and may be transparent.

Block 64, the photoresist is covered with a mask for exposure, and etching may be carried out.

Particularly, after the upper surface of the planarization layer 72 is coated with the photoresist 73, the photoresist 73 may be covered with a mask 74 provided with patterns distributed in an array manner; after exposure, the photoresist corresponding to transmitting areas of the mask 74 may be developed away after development, and the parts, not protected by the photoresist 73, of the planarization layer 72 may be etched away; and after being etched, the planarization layer 72 provided with a plurality of convex areas 721 and a plurality of concave areas 722 may be obtained, as shown in FIG. 8.

Block 65, the rest of the photoresist may be stripped, and common touch electrodes may be formed in the concave areas of the planarization layer.

Particularly, the rest of the photoresist 73 may be stripped, and common touch electrodes 74 may be formed in the concave areas 722 of the planarization layer 72, as shown in FIG. 9.

The common touch electrodes 74 may be disposed in the concave areas 722 and may have a thickness identical with a height of the convex areas 721 of the planarization layer 72; the common touch electrodes 74 may be made from indium tin oxide and have thickness of 60 nm.

Block 66, a dielectric layer may be formed on the planarization layer and the common touch electrodes.

Particularly, a dielectric layer 75 may be formed on the planarization layer 72 and the common touch electrodes 74 to finally form an array substrate.

Different from the related art, the planarization layer obtained through the array substrate manufacturing method of this embodiment may be provided with the plurality of convex areas and the plurality of concave areas, and the common touch electrodes may be disposed in the concave areas, so that the thickness of the common touch electrodes may be made identical with the height of the convex areas, thus, ensuring that the surface of the array substrate may be flat and effectively avoiding the abnormal display of a display panel caused by gap inconsistencies.

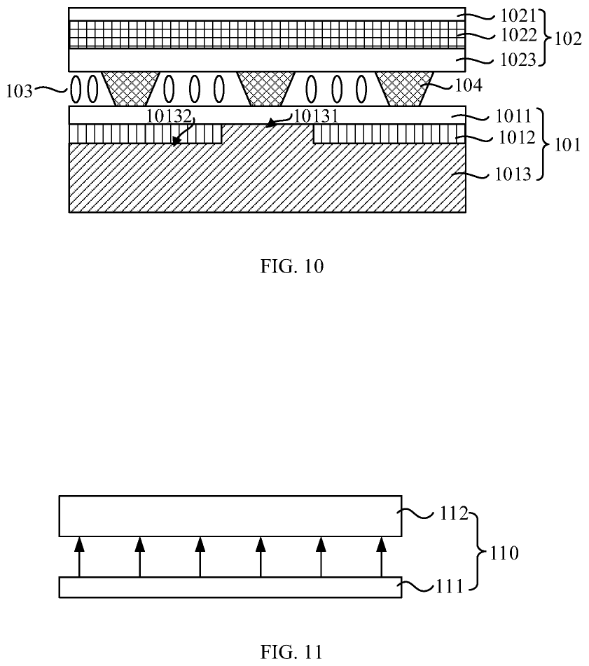

Please refer to FIG. 10, which is a structural view of one embodiment of a display panel of the present disclosure. The display panel may comprise an array substrate 101, a color filter substrate 102 and a liquid crystal layer 103 located between the color filter substrate 102 and the array substrate 101.

The array substrate 101 may be the array substrate in the above-mentioned embodiments, or an array substrate manufactured through the array substrate manufacturing method in the above-mentioned embodiments, and the shape of the color filter substrate 102 may correspond to the shape of the array substrate 101.

The array substrate 101 may comprise a planarization layer 1013, common touch electrodes 1012 and a dielectric layer 1011, which are disposed in a stacked manner.

The planarization layer 1013 may be provided with a plurality of convex areas 10131 and a plurality of concave areas 10132 which are distributed in an array manner, and the common touch electrodes 1012 may be disposed in the concave areas 10132.

The color filter substrate 102 may comprise a substrate layer 1021, a color filter layer 1022 and a protective layer 1023 which are disposed in a stacked manner, and the protective layer 1023 may be adjacent to the liquid crystal layer 103.

In order to maintain the thickness of the liquid crystal display panel after cell fabrication to ensure a good display effect, support columns 104 may be disposed between the color filter substrate 102 and the array substrate 101.

The multiple support columns 104 may be disposed on the color filter substrate 102 and located between the dielectric layer 1011 and the color filter substrate 102. At least a part of the support columns 104 may be located in the convex areas 10131, and at least another part of the support columns 104 may be located in the areas where the common touch electrodes 1012 are located.

As the support columns 104 have a material hardness greater than the material hardness of an organic layer where the support columns 104 are located, the support columns 104 may effectively provide a certain supporting force when colliding with a hard object, so that the internal film layer may be protected against cracks caused by collisions with the hard object, thus, improving the collision resistance of the display panel.

After cell fabrication of the color filter substrate 102 and the array substrate 101, the liquid crystal layer 103 may be injected between the color filter substrate 102 and the array substrate 101, and thus, a display function is realized.

The thickness of the common touch electrodes 1012 may be basically identical with the height of the convex areas 10131, so that the surface of the array substrate 101 may be basically flat, gap inconsistency of the color filter substrate 102 caused by gravity after cell fabrication may be prevented, and the gaps of the display panel may be basically kept consistent after cell fabrication, thus, ensuring the performance and yield of the touch display panel and effectively avoiding abnormal display of the display panel caused by gap inconsistency.

Please refer to FIG. 11, which is a structural view of one embodiment of a display device of the present disclosure. As shown in FIG. 11, the display device 110 may comprise a backlight module 111 and a display panel 112. The display panel 112 may be the display panel in the above-mentioned embodiment.

The above description is only used to explain certain embodiments of the present disclosure, but is not intended to limit the patent scope of the present disclosure. All equivalent structures or equivalent flow transformations based on the contents in the specification and accompanying drawings of the present disclosure, or direct or indirect applications to other relevant technical fields should also fall within the patent protection scope of the present disclosure.

What is claimed is:

1. An array substrate comprising a planarization layer and a plurality of common touch electrodes located on the planarization layer, wherein the planarization layer is provided with a plurality of convex areas and a plurality of concave areas, and the common touch electrodes are located in the concave areas.

2. The array substrate according to claim 1, wherein,
the common touch electrodes have a thickness substantially equal to a maximum height of the convex areas.

3. The array substrate according to claim 1, further comprising a dielectric layer, wherein the planarization layer and the common touch electrodes are covered with the dielectric layer.

4. The array substrate according to claim 1, wherein,
the common touch electrodes are made from indium tin oxide and have a thickness of 60 nm.

5. The array substrate according to claim 1, further comprising a substrate, a gate layer, an active layer, a source/drain layer and an insulation layer which are disposed in a stacked manner, wherein the planarization layer is disposed on the insulation layer.

6. An array substrate manufacturing method comprising:
providing a substrate; and
sequentially manufacturing a planarization layer and a plurality of common touch electrodes on the substrate to form an array substrate;
wherein, the planarization layer is provided with a plurality of convex areas and a plurality of concave areas, and the common touch electrodes are located in the concave areas.

7. The array substrate manufacturing method according to claim 6 further comprising:
forming the planarization layer on the substrate;
coating an upper surface of the planarization layer with a layer of photoresist;
covering the photoresist with a mask for exposure; and
etching and stripping the photoresist, and forming the common touch electrodes in the concave areas of the planarization layer.

8. The array substrate manufacturing method according to claim 7, wherein,
the photoresist is positive photoresist, and the mask is provided with patterns distributed in an arrayed manner.

9. The array substrate manufacturing method according to claim 7 further comprising:
forming a dielectric layer covering the planarization layer and the common touch electrodes.

10. The array substrate manufacturing method according to claim 6, wherein,
the common touch electrodes have a thickness substantially equal to a maximum height of the convex areas.

11. The array substrate manufacturing method according to claim 6, wherein,
the common touch electrodes are made from indium tin oxide and have a thickness of 60 nm.

12. The array substrate manufacturing method according to claim 6, wherein,
the forming the planarization layer on the substrate comprises:
sequentially forming a gate layer, an active layer, a source/drain layer, an insulation layer and the planarization layer on the substrate.

13. A display panel comprising an array substrate, a color filter substrate and a liquid crystal layer located between the color filter substrate and the array substrate, wherein the array substrate comprises a planarization layer and a plurality of common touch electrodes located on the planarization layer; the planarization layer is provided with a plurality of convex areas and a plurality of concave areas, and the common touch electrodes are located in the concave areas; and the color filter substrate corresponds to the array substrate in shape.

14. The display panel according to claim 13, wherein,
the common touch electrodes have a thickness substantially equal to a maximum height of the convex areas.

15. The display panel according to claim 13, wherein,
the array substrate further comprises a dielectric layer, and the planarization layer and the common touch electrodes are covered with the dielectric layer.

16. The display panel according to claim 15, wherein,
a plurality of support columns are disposed on the color filter substrate and located between the diameter layer and the color filter substrate.

17. The display panel according to claim 16, wherein,
at least some of the plurality of support columns correspond to the convex areas, and at least the rest of support columns correspond to areas where the common touch electrodes are located.

18. The display panel according to claim 13, wherein,
the common touch electrodes are made from indium tin oxide and have a thickness of 60 nm.

19. The display panel according to claim 13, wherein,
the array substrate further comprises a substrate, a gate layer, an active layer, a source/drain layer and an insulation layer which are disposed in a stacked manner, and the planarization layer is located on the insulation layer.

20. The display panel according to claim 13, wherein,
the color filter substrate comprises a substrate layer, a color filter layer and a protective layer which are disposed in a stacked manner, and the protective layer is adjacent to the liquid crystal layer.
